(19) United States
(12) Patent Application Publication
(10) Pub. No.: US 2013/0270571 A1
(43) Pub. Date: Oct. 17, 2013

(54) SCHOTTKY BARRIER DIODE AND MANUFACTURING METHOD THEREOF

(71) Applicants: Chih-Fang Huang, Hsinchu City (TW); Tsung-Yu Yang, Kaohsiung City (TW); Ting-Fu Chang, Taipei City (TW); Tsung-Yi Huang, Hsinchu City (TW); Chien-Wei Chiu, Yunlin County (TW)

(72) Inventors: Chih-Fang Huang, Hsinchu City (TW); Tsung-Yu Yang, Kaohsiung City (TW); Ting-Fu Chang, Taipei City (TW); Tsung-Yi Huang, Hsinchu City (TW); Chien-Wei Chiu, Yunlin County (TW)

(73) Assignee: Richtek Technology Corporation

(21) Appl. No.: 13/448,163

(22) Filed: Apr. 16, 2012

(51) Int. Cl. H01L 29/20; H01L 21/20

(52) U.S. Cl. 257/76; 438/478; 257/E29.089; 257/E21.09

(57) ABSTRACT

The present invention discloses a Schottky barrier diode (SBD) and a manufacturing method thereof. The SBD is formed on a substrate. The SBD includes: a gallium nitride (GaN) layer; an aluminum gallium nitride (AlGaN), formed on the GaN layer; a high work function conductive layer, formed on the AlGaN layer, wherein a first Schottky contact is formed between the high work function conductive layer and the AlGaN layer; a low work function conductive layer, formed on the AlGaN layer, wherein a second Schottky contact is formed between the low work function conductive layer and the AlGaN layer; and an ohmic contact metal layer, formed on the AlGaN layer, wherein an ohmic contact is formed between the ohmic contact metal layer and the AlGaN layer, and wherein the ohmic contact conductive layer is separated from the high and low work function conductive layers by a dielectric layer.

### BACKGROUND OF THE INVENTION

1. Field of Invention

The present invention relates to a Schottky barrier diode (SBD) and a manufacturing method of an SBD; particularly, it relates to such SBD and manufacturing method wherein the leakage current of the SBD is decreased.

2. Description of Related Art

A Schottky barrier diode (SBD) is a semiconductor device. Compared to a P-N junction diode, the SBD has a higher forward current and a shorter recovery time in operation because of a Schottky barrier formed by Schottky contact between a metal layer and a semiconductor layer. However, the SBD has a higher leakage current and therefore more power loss in a reverse biased operation.

To overcome the drawback in the prior art, the present invention proposes an SBD and a manufacturing method thereof which decrease the leakage current in the reverse biased operation, such that the power loss is decreased.

### SUMMARY OF THE INVENTION

A first objective of the present invention is to provide a Schottky barrier diode (SBD).

A second objective of the present invention is to provide a manufacturing method of an SBD.

To achieve the objectives mentioned above, from one perspective, the present invention provides a Schottky barrier diode (SBD) formed on a substrate, including: a gallium nitride (GaN) layer formed on an upper surface of the substrate; an aluminum gallium nitride (AlGaN) layer formed on the GaN layer, wherein a cathode is formed by the GaN layer and the AlGaN layer; a high work function conductive layer formed on the AlGaN layer, wherein a first Schottky contact is formed between the high work function conductive layer and the AlGaN layer; a low work function conductive layer formed on the AlGaN layer, wherein a second Schottky contact is formed between the low work function conductive layer and the AlGaN layer; and an ohmic contact conductive layer formed on the AlGaN layer, wherein an ohmic contact is formed between the ohmic contact conductive layer and the AlGaN layer, and wherein the ohmic contact conductive layer is separated from the high and low work function conductive layers by a dielectric layer.

From another perspective, the present invention provides a manufacturing method of an SBD, including: forming a gallium nitride (GaN) layer on a substrate; forming an aluminum gallium nitride (AlGaN) layer on the GaN layer, wherein a cathode is formed by the GaN layer and the AlGaN layer; forming a high work function conductive layer on the AlGaN layer, wherein a first Schottky contact is formed between the high work function conductive layer and the AlGaN layer; forming a low work function conductive layer on the AlGaN layer, wherein a second Schottky contact is formed between the low work function conductive layer and the AlGaN layer; and forming an ohmic contact conductive layer on the AlGaN layer, wherein an ohmic contact is formed between the ohmic contact conductive layer and the AlGaN layer, and forming a dielectric layer, wherein the ohmic contact conductive layer is separated from the high and low work function conductive layers by a dielectric layer.

In one embodiment, the dielectric layer preferably surrounds the high work function conductive layer and the low work function conductive layer from a top view of a cross-section along a level line, and the ohmic contact conductive layer surrounds the dielectric layer from the top view of the cross-section along the level line.

In the aforementioned embodiment, more preferably, the low work function conductive layer is located in the high work function conductive layer from the top view of the cross-section along the level line.

In another embodiment, the substrate preferably includes an insulating substrate or a conductive substrate.

In another preferable embodiment, the high work function conductive layer includes a tungsten (W) layer or a gold (Au) layer, and the low work function conductive layer includes an aluminum (Al) layer or a titanium (Ti) layer.

The objectives, technical details, features, and effects of the present invention will be better understood with regard to the detailed description of the embodiments below.

### BRIEF DESCRIPTION OF THE DRAWINGS

FIGS. 1A-1C show a first embodiment of the present invention.

FIGS. 2A-2C show several layout embodiments of the first embodiment from top view.

FIG. 3 shows I-V characteristic curves of SBDs having anodes formed by high and low work function materials, respectively.

FIG. 4 shows simulation I-V characteristic curves of SBDs according to the present invention.

FIGS. 5A-5C show energy band diagrams of Schottky contacts to explain the mechanism of the present invention.

FIG. 6 shows another embodiment of the present invention.

FIG. 7 shows examples of work functions of metals.

### DESCRIPTION OF THE PREFERRED EMBODIMENTS

The drawings as referred to throughout the description of the present invention are for illustration only, but not drawn according to actual scale.

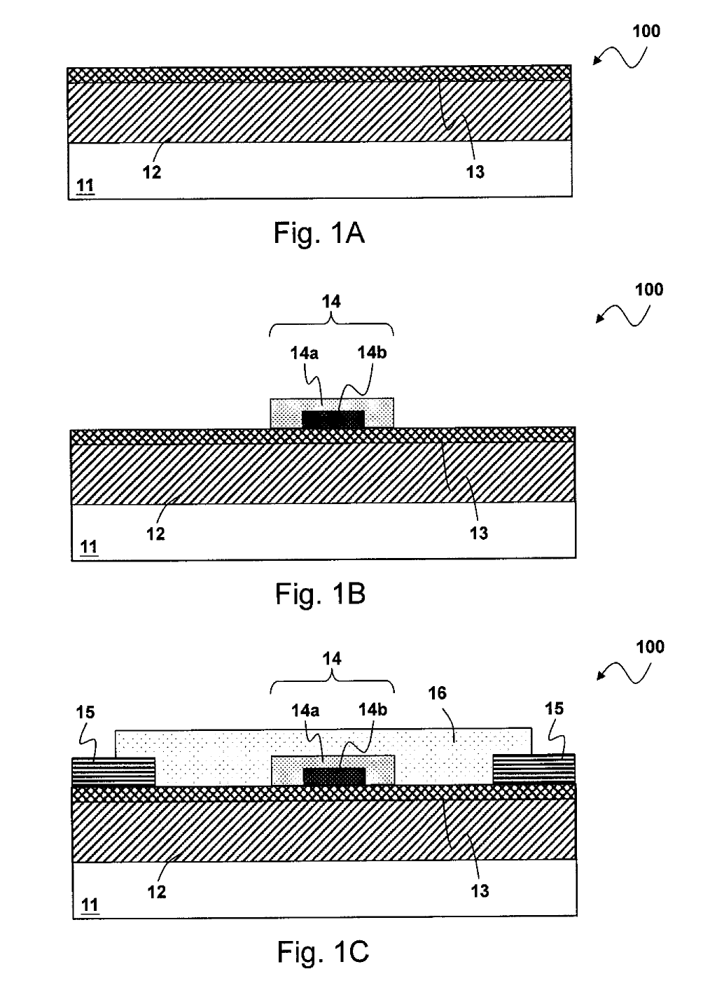

FIGS. 1A-1C show a first embodiment of the present invention. FIGS. 1A-1C are schematic cross-section diagrams showing a manufacturing flow of a Schottky barrier diode (SBD) 100 according to this embodiment. As shown in FIG. 1A, a gallium nitride (GaN) layer 12 is formed on an upper surface of a substrate 11. The substrate 11 for example is but not limited to a sapphire substrate or a conductive substrate, such as a silicon carbide (SiC) substrate. Next, an aluminum gallium nitride (AlGaN) layer 13 is formed on the GaN layer 12, wherein a cathode is formed by the GaN layer 12 and the AlGaN layer 13.

Next, referring to FIG. 1B, a high work function conductive layer 14a and a low work function conductive layer 14b are formed on the AlGaN layer 13, wherein a first Schottky contact is formed between the high work function conductive layer 14a and the AlGaN layer 13, and a second Schottky contact is formed between the low work function conductive layer 14b and the AlGaN layer 13. The high work function conductive layer 14a and the low work function conductive layer 14b are for example made of metal materials, and the work function of the low work function conductive layer 14b is lower than the work function of the high work function conductive layer 14a. The high work function conductive layer 14a and the low work function conductive layer 14b are electrically connected with each other, and they form an anode 14 of the SBD 100.

Next, as shown in FIG. 1C, an ohmic contact conductive layer 15 is formed on the AlGaN layer 13, wherein an ohmic contact is formed between the ohmic contact conductive layer 15 and the AlGaN layer 13. The ohmic contact conductive layer 15 and the anode 14 are separated by a dielectric layer 16.

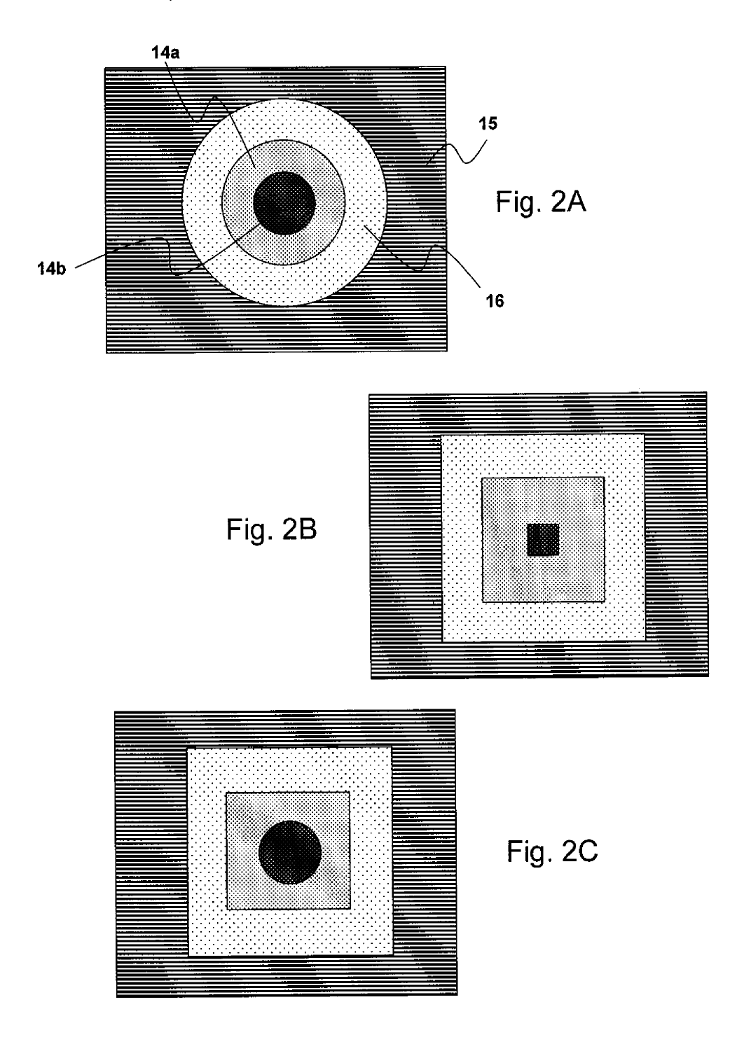

FIGS. 2A-2C show several layout embodiments of the first embodiment from a top view of a cross-section taken along the level line II-II of FIG. 1C. As shown in FIGS. 2A-2C, the sizes and the shapes of the dielectric layer 16, the high work function conductive layer 14a, and the low work function conductive layer 14b are not limited, as long as the high work function conductive layer 14a and the low work function conductive layer 14b are electrically connected with each other, and the ohmic contact conductive layer 15 and the anode 14 are separated by the dielectric layer 16.

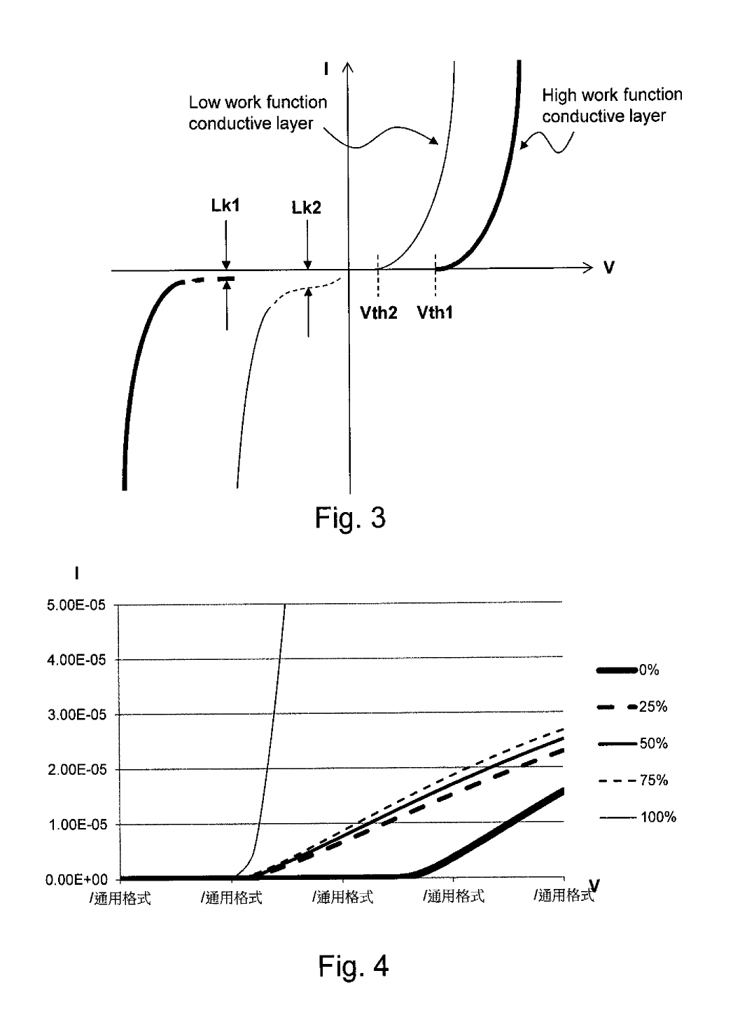

FIG. 3 shows that the present invention is advantageous over the prior art by I-V characteristic curves of SBDs with a high work function anode and a low work function anode, respectively. As shown in FIG. 3, the I-V characteristic curve of the SBD with the high work function anode is indicated by the bold line. When the SBD with the high work function anode operates in forward biased condition, the conductive threshold voltage Vth1 of the SBD is relatively higher, but when the SBD with the high work function anode operates in reverse biased condition, the leakage current Lk1 of the SBD is relatively lower and the breakdown voltage of the SBD is relatively higher. The I-V characteristic curve of the SBD with the low work function anode is indicated by the thin line. Compared to the SBD with the high work function anode, when the SBD with the low work function anode operates in forward biased condition, the conductive threshold voltage Vth2 of the SBD is relatively lower, but when the SBD with the low work function anode operates in reverse biased condition, the leakage current Lk2 of the SBD is relatively higher and the breakdown voltage of the SBD is relatively lower. The SBD of the present invention has a conductive threshold voltage a little higher than the threshold voltage Vth2 in forward biased condition, while a leakage current significantly lower than the leakage current Lk2 and a higher breakdown voltage in reverse biased condition.

FIG. 4 shows simulation I-V characteristic curves of SBDs of the present invention with different width ratios between the high work function conductive layer and low work function conductive layer. From FIG. 4 and the first quadrant of FIG. 3, it is clear that when the width ratio of the low work function conductive layer in the anode is 25% or higher, the conductive threshold voltage of the SBD of the present becomes significantly lower than the conductive threshold voltage of an SBD with the anode formed completely by the high work function metal.

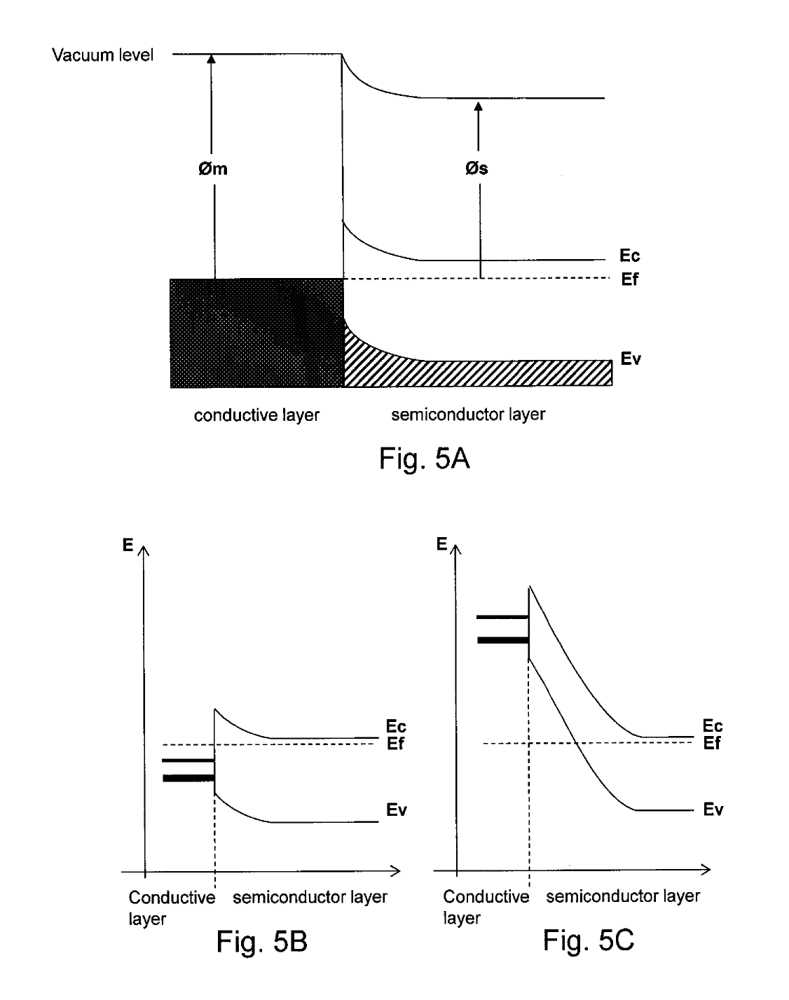

FIGS. 5A-5C show energy band diagrams of Schottky contacts, to explain the mechanism of the present invention. FIG. 5A shows a conventional energy band diagram of the metal-semiconductor junction of a Schottky contact. Øm is metal work function, Øs is semiconductor work function, Ef is Fermi level, and Ec and Ev are conduction band and valance band of the semiconductor, respectively. The relations between Øm, Øs, Ef, Ec, and Ev, as well known by those skilled in the art, so details thereof are omitted here. FIGS. 5B and 5C show energy band diagrams of Schottky contacts in forward biased condition and reverse biased condition, respectively. The band gaps of the high work function conductive layer and the low work function conductive layer in forward biased condition and reverse biased condition are indicated by the thickest segment and the less thicker segment. As shown in the figures, when the SBD of the present invention operates in the forward biased condition, the combination of the high and low work function metals decreases the band gap between the conductive layer and the semiconductor layer, and when the SBD of the present invention operates in the reverse biased condition, the combination of the high and low work function metals increases the band gap between the conductive layer and the semiconductor layer.

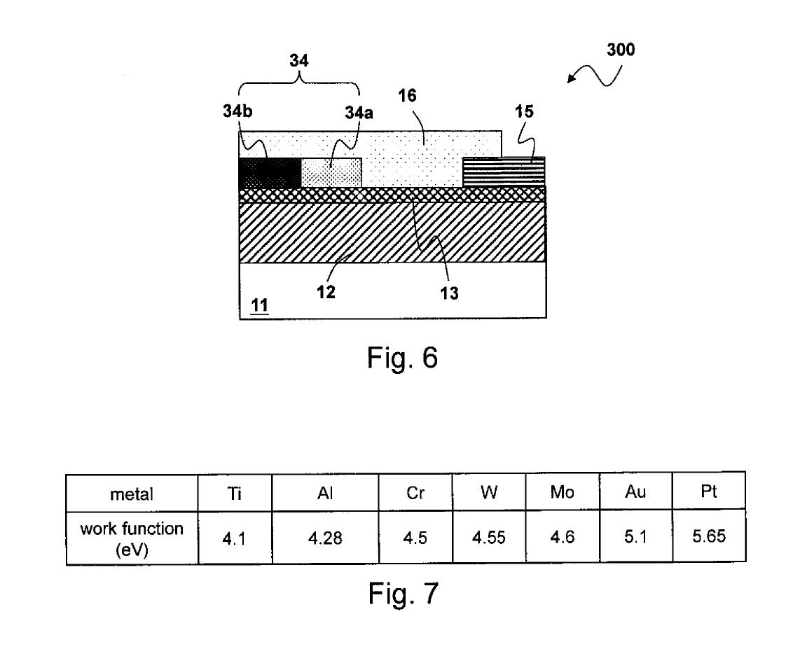

FIG. 6 shows another embodiment of the present invention. This embodiment is different from the first embodiment in that, an anode 34 of an SBD 300 in this embodiment includes a high work function conductive layer 34a and a low work function conductive layer 34b electrically connected with each other, wherein the low work function conductive layer 34b is not surrounded by the high work function conductive layer 34a, but they are connected side-by-side laterally from the cross-section view. The width ratio of the high work function conductive layer 34a and the low work function conductive layer 34b may be adjusted according to the requirement.

Note that, for example similar to FIGS. 2A-2C, the dielectric layer 16 may surround the anode 34 from a top view of a cross section taken along the level line in FIG. 6, and the ohmic contact conductive layer 15 may surround the dielectric layer 16 from the top view. Besides, the high work function conductive layer 34a and the low work function conductive layer 34b may be any combination of conductive layers with different work functions, as long as the work function of the high work function conductive layer 34a is relatively higher than the work function of the low work function conductive layer 34b. FIG. 7 shows examples of work functions of metals. Note that the work functions listed in FIG. 7 are only for reference, and they may be changed because of the lattice or the topography, etc. of the metals. Referring to FIG. 7, various metals may be candidates of the high work function conductive layer 34a and the low work function conductive layer 34b, for example but not limited to, tungsten (W) or gold (Au) as the high work function conductive layer 34a, and aluminum (Al) or titanium (Ti) as the low work function conductive layer 34b. Besides, the high and low work function conductive layers 34a and 34b may also include metal silicide, such as: TiSi2, CrSi2, MoSi2, PtSi2, etc.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. For example, other process steps or structures which do not affect the primary characteristics of the device, such as an ohmic contact region as the cathode of the SBD, which for example may be defined and etched before forming the ohmic contact conductive layer 15. For another example, the anode may be formed by three or more materials instead of two. In view of the foregoing, the spirit of the present invention should cover all such and other modifications and variations, which should be interpreted to fall within the scope of the following claims and their equivalents.

What is claimed is:

1. A Schottky barrier diode (SBD) formed on a substrate, comprising:
a gallium nitride (GaN) layer formed on an upper surface of the substrate;
an aluminum gallium nitride (AlGaN) layer formed on the GaN layer, wherein a cathode is formed by the GaN layer and the AlGaN layer;
a high work function conductive layer formed on the AlGaN layer, wherein a first Schottky contact is formed between the high work function conductive layer and the AlGaN layer;
a low work function conductive layer formed on the AlGaN layer, wherein a second Schottky contact is formed between the low work function conductive layer and the AlGaN layer; and
an ohmic contact conductive layer formed on the AlGaN layer, wherein an ohmic contact is formed between the ohmic contact conductive layer and the AlGaN layer, and wherein the ohmic contact conductive layer is separated from the high and low work function conductive layers by a dielectric layer.

2. The SBD of claim 1, wherein the dielectric layer surrounds the high work function conductive layer and the low work function conductive layer from a top view of a cross-section along a level line, and the ohmic contact conductive layer surrounds the dielectric layer from the top view of the cross-section along the level line.

3. The SBD of claim 2, wherein the low work function conductive layer is located in the high work function conductive layer from the top view of the cross-section along the level line.

4. The SBD of claim 2, wherein the substrate includes an insulating substrate or a conductive substrate.

5. The SBD of claim 1, wherein the high work function conductive layer includes a tungsten (W) layer or a gold (Au) layer, and the low work function conductive layer includes an aluminum (Al) layer or a titanium (Ti) layer.

6. A manufacturing method of a Schottky barrier diode (SBD), comprising:
forming a gallium nitride (GaN) layer on a substrate;
forming an aluminum gallium nitride (AlGaN) layer on the GaN layer, wherein a cathode is formed by the GaN layer and the AlGaN layer;
forming a high work function conductive layer on the AlGaN layer, wherein a first Schottky contact is formed between the high work function conductive layer and the AlGaN layer;
forming a low work function conductive layer on the AlGaN layer, wherein a second Schottky contact is formed between the low work function conductive layer and the AlGaN layer;
forming an ohmic contact conductive layer on the AlGaN layer, wherein an ohmic contact is formed between the ohmic contact conductive layer and the AlGaN layer, and
forming a dielectric layer, wherein the ohmic contact conductive layer is separated from the high and low work function conductive layers by the dielectric layer.

7. The manufacturing method of claim 6, wherein the dielectric layer surrounds the high work function conductive layer and the low work function conductive layer from a top view of a cross-section along a level line, and the ohmic contact conductive layer surrounds the dielectric layer from the top view of the cross-section along the level line.

8. The manufacturing method of claim 7, wherein the low work function conductive layer is located in the high work function conductive layer from the top view of the cross-section along the level line.

9. The manufacturing method of claim 6, wherein the substrate includes an insulating substrate or a conductive substrate.

10. The manufacturing method of claim 6, wherein the high work function conductive layer includes a tungsten (W) layer or a gold (Au) layer, and the low work function conductive layer includes an aluminum (Al) layer or a titanium (Ti) layer.
